(19) United States
(12) Patent Application Publication
(10) Pub. No.: US 2010/0202181 A1
(43) Pub. Date: Aug. 12, 2010

(54) SEMICONDUCTOR MEMORY DEVICE

(76) Inventors: Takaki HASHIMOTO, Yokohama (JP); Hidefumi Mukai, Kawasaki-shi (JP); Yasunobu Kai, Yokohama-shi (JP); Toshiya Kotani, Machida-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/561,531

(22) Filed: Sep. 17, 2009

(30) Foreign Application Priority Data
Feb. 10, 2009 (JP) 2009-028948

(51) Int. Cl. G11C 5/06

(52) U.S. Cl. 365/63

(57) ABSTRACT

A semiconductor memory device includes a semiconductor substrate on which memory cells are formed. Interconnects are arranged along a first direction above the semiconductor substrate, and have regular intervals along a second direction perpendicular to the first direction. Interconnect contacts connect the interconnects and the semiconductor substrate, are arranged on three or more rows. The center of each of two of the interconnect contacts which are connected to the interconnects adjacent in the second direction deviate from each other along the first direction.

### CROSS-REFERENCE TO RELATED APPLICATIONS

This application is based upon and claims the benefit of priority from prior Japanese Patent Application No. 2009-028948, filed Feb. 10, 2009, the entire contents of which are incorporated herein by reference.

### BACKGROUND OF THE INVENTION

1. Field of the Invention

The present invention relates to a semiconductor memory device. More particularly, the present invention relates to a nonvolatile semiconductor memory device which uses a nonvolatile memory cell as a storage element.

2. Description of the Related Art

A NAND-cell type EEPROM (NAND flash memory) is drawing attention as a semiconductor memory device. The NAND flash memory uses, as a nonvolatile memory cell, a metal oxide semiconductor (MOS) transistor of a stack gate structure including a charge accumulation layer and a control gate thereover.

In the NAND flash memory, a bit line contact is connected to a diffusion layer of a select gate transistor. It is known that, in order to improve integration, bit line contacts adjacent in a bit line direction are laid out zigzag along the bit line direction (staggered-for-two arrangement) (see, for example, Japanese Patent No. 3441140).

According to this conventional technique, the pattering condition of interconnects in the NAND flash memory is HP×NA/λ<0.25. Therefore, this technique is useful for the improvement in the integration. Here, HP (half pitch) is the width of a bit line, NA is the numerical aperture of a projection lens in a lithography apparatus, and λ is the wavelength of light from an illumination optical system in the lithography apparatus. An example of a condition that corresponds to the above-mentioned interconnect patterning condition includes: HP=32 nm, NA=1.20 and λ=193 nm. This interconnect is formed by, for example, a double patterning process such as a sidewall fabrication process.

However, an increasingly significant problem in the NAND flash memory which requires “HP×NA/λ<0.15” as the interconnect patterning condition is that the bit line contacts cannot be stably formed. An example of a condition that corresponds to this interconnect patterning condition includes: HP=20 nm, NA=1.35 and λ=193 nm. This interconnect is also formed by a double patterning process such as a sidewall fabrication process.

One way to solve this problem is to lengthen the horizontal sectional shape of the bit line contact in a direction extending along the bit line (word line direction) so that a process margin in a lithography step can be ensured.

However, lengthened bit line contact as such require a larger distance between select gate lines each connected to the gate of the select gate transistor. This leads to an increased chip area.

### BRIEF SUMMARY OF THE INVENTION

According to an aspect of the present invention, there is provided a semiconductor memory device comprising: a semiconductor substrate on which memory cells are formed; interconnects arranged along a first direction above the semiconductor substrate and having regular intervals along a second direction perpendicular to the first direction; and interconnect contacts which connect the interconnects and the semiconductor substrate and are arranged on three or more rows, a center of each of two of the interconnect contacts connected to the interconnects adjacent in the second direction deviating from each other along the first direction.

According to another aspect of the present invention, there is provided a semiconductor memory device comprising: a semiconductor substrate on which memory cells are formed; bit lines arranged along a first direction above the semiconductor substrate and having regular intervals along a second direction perpendicular to the first direction; and bit line contacts which connect the bit lines and the semiconductor substrate, a predetermined number of the memory cells connected in series constituting a first set and a second set adjacent to the first set, the bit line contacts being provided between select gate lines between the first and second sets, the bit line contacts being arranged on three or more rows, a center of each of two of the bit line contacts connected to the bit lines adjacent in the second direction deviating from each other along the first direction.

### BRIEF DESCRIPTION OF THE SEVERAL VIEWS OF THE DRAWING

FIG. 1 is a plan view showing a cell array in a semiconductor memory device (NAND flash memory) according to the first embodiment of the present invention;

FIG. 2 shows the basic configuration of a lithography apparatus used to manufacture the NAND flash memory according to the first embodiment;

FIG. 3 is a plan view showing one example of a photomask used to manufacture the NAND flash memory according to the first embodiment;

FIG. 4 is a plan view showing an example of the configuration of an illumination optical system in the lithography apparatus according to the first embodiment;

FIG. 5 is a graph for explaining the relation between the numerical aperture of a projection lens, and the pitch of bit line contacts in a bit line direction and the pitch thereof in a word line direction, according to the first embodiment;

FIG. 6 is a plan view showing another cell array in the NAND flash memory according to the first embodiment;

FIG. 7 is a plan view showing a cell array in a semiconductor memory device (NAND flash memory) according to the second embodiment of the present invention;

FIG. 8 is a plan view showing one example of a photomask used to manufacture the NAND flash memory according to the second embodiment;

FIG. 9 is a plan view showing another cell array in the NAND flash memory according to the second embodiment;

FIG. 10 is a plan view showing another cell array in the NAND flash memory according to the second embodiment;

FIG. 11 is a plan view showing another cell array in the NAND flash memory according to the second embodiment;

FIG. 12 is a plan view showing another cell array in the NAND flash memory according to the second embodiment;

FIG. 13 is a plan view showing another cell array in the NAND flash memory according to the second embodiment;

FIG. 14 is a plan view showing another example of the configuration of the illumination optical system in the lithography apparatus; and

FIG. 15 is a plan view showing still another example of the configuration of the illumination optical system in the lithography apparatus.

### DETAILED DESCRIPTION OF THE INVENTION

Embodiments of the present invention will be described with reference to the accompanying drawings. It should be noted that the drawings are schematic ones and so are not to scale. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### First Embodiment

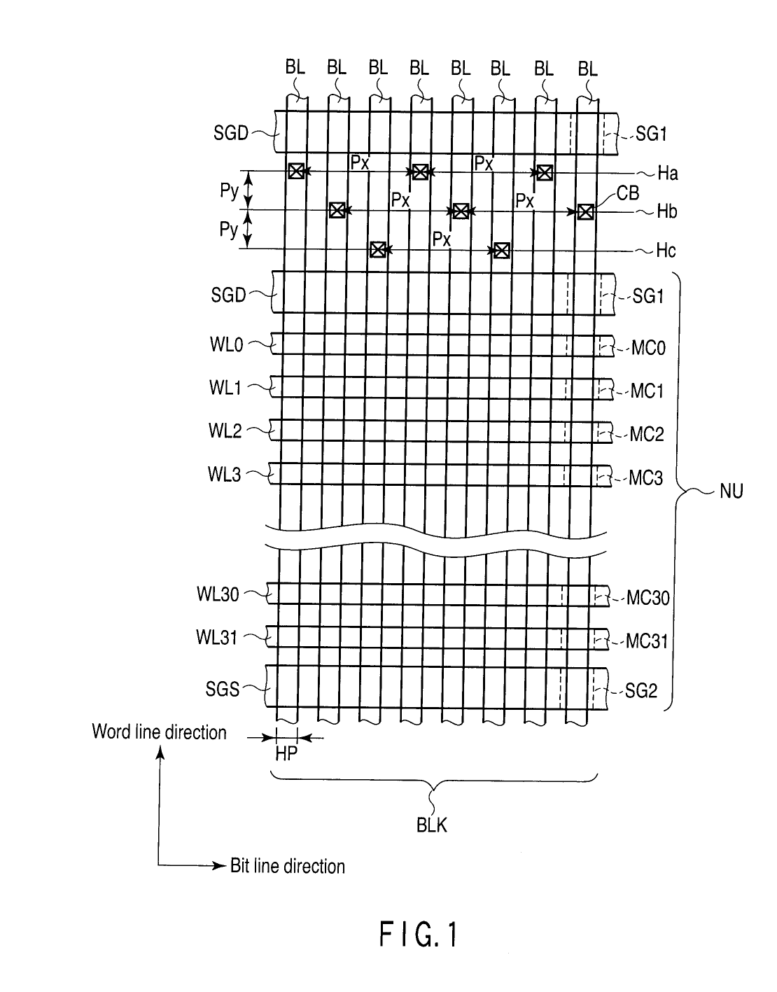

FIG. 1 shows an example of the configuration of a memory cell array in a semiconductor memory device according to the first embodiment of the present invention. In the first embodiment, a NAND flash memory (NAND cell type EEPROM) is described as an example of a nonvolatile semiconductor memory device using a nonvolatile memory cell. Moreover, in this example, bit line contacts are arranged in a staggered-for-three form.

As shown in FIG. 1, the memory cell array is constituted of NAND cell units (NAND strings) NU arranged in a matrix. Each of the NAND cell units NU has nonvolatile memory cells MC0 to MC31, and select gate transistors (MOS transistors) SG1 and SG2. Data in the nonvolatile memory cells MC0 to MC31 can be electrically rewritable. The select gate transistors SG1 and SG2 connect both ends of each chain of the nonvolatile memory cells MC0 to MC31 to a bit line BL and a source line (not shown), respectively.

A MOS transistor of a stack gate structure having a charge accumulation layer (e.g., a floating gate) and a control gate provided thereover is used as each of the nonvolatile memory cells MC0 to MC31. In general, binary data is stored, wherein a state with a high threshold voltage (state with a positive threshold voltage) is used as “0” data, while a state with a low threshold voltage (state with a negative threshold voltage) is used as “1” data. Electrons are injected in the floating gate in the high threshold voltage state, while electrons are emitted from the floating gate in the low threshold value state.

In FIG. 1, the control gates of the memory cells MC0 to MC31 are connected to word lines WL0 to WL31, respectively. The word lines WL0 to WL31 are perpendicular to the bit lines BL. The gates of the select gate transistors SG1 and SG2 are connected to select gate lines SGD and SGS, respectively. The select gate lines SGD and SGS are in parallel with the word lines WL0 to WL31.

A set of NAND cell units NU sharing the word lines WL0 to WL31 constitutes a block BLK. The block BLK is a unit for erasing data. FIG. 1 representatively illustrates one block BLK. However, in general, blocks BLK are arranged in a direction extending along the bit line BL (word line direction, or first direction). Adjacent two blocks BLK are line-symmetrically arranged. That is, the select gate transistor SG1 of a block BLK shares a drain with the select gate transistor SG1 of an adjacent block BLK, and the select gate transistor SG2 of a block BLK shares a source with the select gate transistor SG2 of an adjacent block BLK.

Between the select gate lines SGD of the adjacent blocks BLK, bit line contacts CB are arranged in three rows along a bit line direction (second direction). Each of the bit line contacts CB connects each bit line BL to each drain of the select gate transistor SG1. In the present embodiment, the bit line contacts CB connected to the bit lines BL are arranged in a so-called staggered-for-three form. That is, the respective bit line contacts CB for the adjacent two bit lines deviate from each other in the word line direction. As a result, three rows of bit line contacts CB along the word line direction are arranged along the bit line direction.

For example, the bit line contacts CB are arranged at a pitch Px (first interval) on each of three virtual parallel lines Ha, Hb, Hc extending along the bit line direction. The bit line contacts CB arranged on the first parallel line Ha and the bit line contacts CB arranged on the second parallel line Hb have a pitch Py (second interval) therebetween along the word line direction. The bit line contacts CB arranged on the second parallel line Hb and the bit line contacts CB arranged on the third parallel line Hc also have a pitch Py therebetween along the word line direction. That is, the bit line contacts CB arranged on the second parallel line Hb are shifted by the pitch Py from the bit line contacts CB arranged on the first parallel line Ha. The bit line contacts CB arranged on the third parallel line Hc are shifted by the pitch Py from the bit line contacts CB arranged on the second parallel line Hb.

Here, suppose a NAND flash memory which requires HP×NA/λ<0.15 as the patterning condition in a wiring step. NA is the numerical aperture of a projection lens (projection optical system) in a lithography apparatus, and λ is the wavelength of illumination light from an illumination optical system in the lithography apparatus. In the present embodiment, while the width of the bit line BL is HP, the bit line contacts CB in each row have intervals of 6 HP. That is, when there are three parallel lines, the pitch Px in the bit line direction between the bit line contacts CB formed on each row is three times the pitch of the bit lines BL. Thus, for each of the bit lines BL apart by 6HP, the bit line contacts CB are arranged at the same position (on the same parallel line) in the word line direction. Then, for adjacent bit lines BL, the bit line contacts CB in the respective rows are shifted by 2HP along the word line direction.

In the present embodiment, the minimum distance (Px/3) between the bit line contacts CB adjacent in the bit line direction may be greater than the pitch of the bit lines BL (2HP). Moreover, when the above-mentioned relation of the pitches Px and Py is satisfied and the centers of the bit line contacts CB are located on the respective parallel lines Ha, Hb, and Hc, the distance between the parallel lines Ha, Hb, and Hc is equal to Py.

Thus, the bit line contacts CB arranged on the bit lines BL are arranged in a staggered-for-three form. Consequently, in a NAND flash memory having thin bit lines BL and having a smaller pitch between the bit lines BL, the bit line contacts CB can be highly accurately laid out.

Now, the basic configuration of the lithography apparatus used to manufacture the above NAND flash memory is described. It is to be noted that details of the lithography apparatus suitably used to form contact holes for the bit line contacts CB are disclosed in the specification of an earlier application (see, for example, Japanese Patent Application No. 2008-330621) and are therefore briefly described.

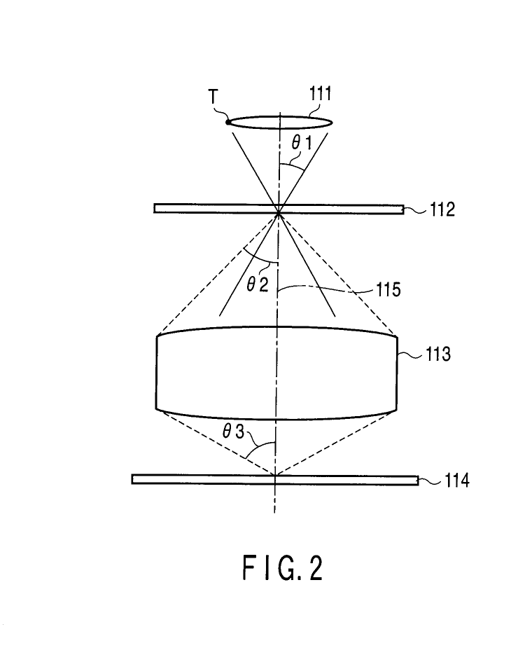

In FIG. 2, 111 denotes an illumination optical system, 112 denotes a photomask, 113 denotes a projection optical system (projection lens), 114 denotes a substrate (semiconductor wafer), and 115 denotes an optical axis. The exit numerical aperture of the illumination optical system 111 is sin(θ1), and the entrance numerical aperture of the projection optical system 113 is sin(θ2). A σ value is defined as sin(θ1)/sin(θ2).

When modified illumination such as dipole illumination is used for the illumination optical system 111, the definition of the σ value is generally extended, so that a σ coordinate system is used. The σ coordinate system is a coordinate system which originates in the optical axis 115 and in which the entrance numerical aperture of the projection optical system 113 is standardized at “1”. Thus, the illumination position at a point T in FIG. 2 on the σ coordinate system is

(σx,σy)=(sin(θ1)/sin(θ2),0).

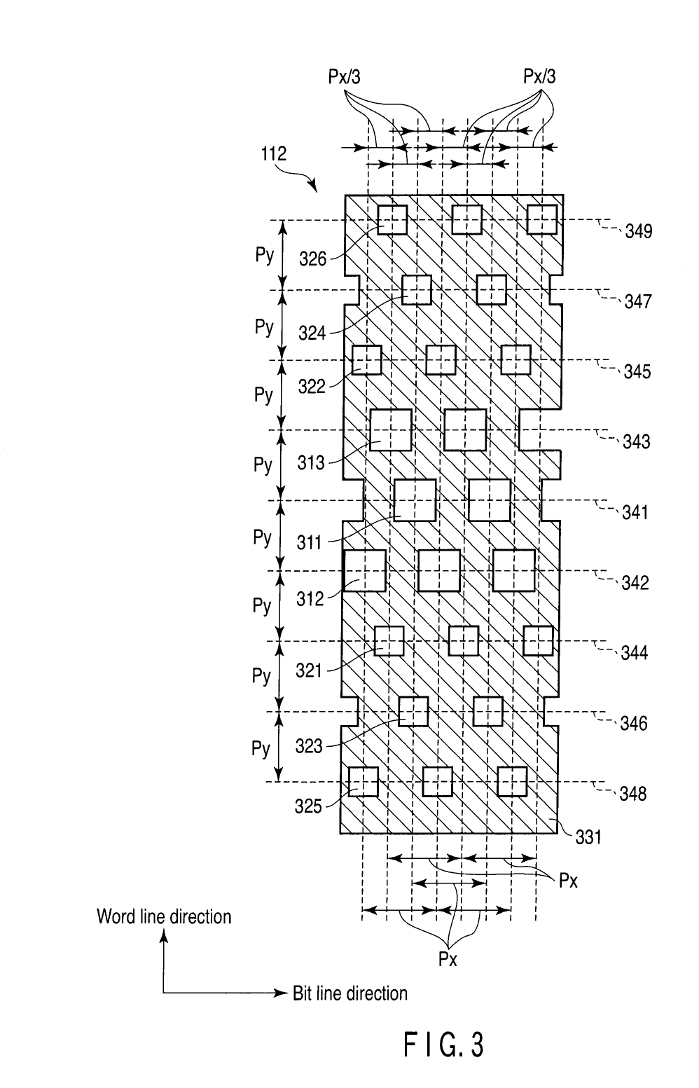

FIG. 3 shows one example of the photomask 112. In this example, the contact holes for the bit line contacts CB in the NAND flash memory are formed. That is, the contact holes are dense hole patterns, and are not arranged in the form of an orthogonal grid, and so-called NAND-CB layers are arranged in a staggered-for-three form.

In FIG. 3, the photomask 112 has sets of openings: main openings (first main openings) 311, main openings (second main openings) 312, main openings (third main openings) 313, assist openings (first assist openings) 321, assist openings (second assist openings) 322, assist openings (third assist openings) 323, assist openings (fourth assist openings) 324, assist openings (fifth assist openings) 325 and assist openings (sixth assist openings) 326. Openings 311, 312, 313, 321, 322, 323, 324, 325 and 326 are enclosed by a light-blocking region (nontransparent region) 331. The light-blocking region 331 is, for example, a light-blocking region in which a chromium film is formed, or a semitransparent halftone phase shift region in which, for example, a molybdenum silicide film is formed.

The main openings 311, 312, and 313 have the same shape and dimensions. The assist openings 321, 322, 323, 324, 325, and 326 have the same shape and dimensions. The assist openings 321, 322, 323, 324, 325, and 326 are smaller than the main openings 311, 312, and 313.

The main openings 311, 312, and 313 are opening patterns (transferred patterns) corresponding to contact hole patterns for the bit line contacts CB. Thus, after a lithography step and a development step, patterns corresponding to the main openings 311, 312, and 313 are formed in a photoresist used for contact hole formation. The assist openings 321, 322, 323, 324, 325, and 326 are auxiliary opening patterns (assist patterns not to be resolved). Therefore, no patterns corresponding to the assist openings 321, 322, 323, 324, 325, and 326 are formed in the photoresist even after the lithography step and the development step.

The main openings 311 are arranged at the pitch Px (second interval) on a straight line (first straight line) 341 extending in the bit line direction. That is, the center of each of the main openings 311 is located on the straight line 341. The main openings 312 adjacent to the main openings 311 are arranged at the pitch Px on a straight line (second straight line) 342 extending along the bit line direction. That is, the center of each of the main openings 312 is located on the straight line 342. The main openings 313 adjacent to the main openings 311 are arranged at the pitch Px on a straight line (third straight line) 343 extending along the bit line direction. That is, the center of each of the main openings 313 is located on the straight line 343.

The straight line 341, the straight line 342 and the straight line 343 are parallel to each other, and the distance (first distance (second interval) in the first direction) between the straight line 341, the straight line 342 and the straight line 343 is equal to Py. Moreover, the main openings 311, the main openings 312 and the main openings 313 deviate by Px/3 (2HP) from each other along the bit line direction.

The assist openings 321 adjacent to the main openings 312 are arranged at the pitch Px on a straight line (fourth straight line) 344 extending along the bit line direction. That is, the center of each of the assist openings 321 is located on the straight line 344. The assist openings 322 adjacent to the main openings 313 are arranged at the pitch Px on a straight line (fifth straight line) 345 extending along the bit line direction. That is, the center of each of the assist openings 322 is located on the straight line 345. The assist openings 323 adjacent to the assist openings 321 are arranged at the pitch Px on a straight line (sixth straight line) 346 extending along the bit line direction. That is, the center of each of the assist openings 323 is located on the straight line 346. The assist openings 324 adjacent to the assist openings 322 are arranged at the pitch Px on a straight line (seventh straight line) 347 extending along the bit line direction. That is, the center of each of the assist openings 324 is located on the straight line 347. The assist openings 325 adjacent to the assist openings 323 are arranged at the pitch Px on a straight line (eighth straight line) 348 extending along the bit line direction. That is, the center of each of the assist openings 325 is located on the straight line 348. The assist openings 326 adjacent to the assist openings 324 are arranged at the pitch Px on a straight line (ninth straight line) 349 extending along the bit line direction. That is, the center of each of the assist openings 326 is located on the straight line 349.

The straight lines 341, 342, 343, 344, 345, 346, 347, 348 and 349 are parallel to each other. The distance (second interval) between the straight line 342 and the straight line 344 is equal to Py. The distance between the straight line 343 and the straight line 345 is also equal to Py. Further, the distance between the straight line 344 and the straight line 346 is equal to Py. The distance between the straight line 345 and the straight line 347 is also equal to Py. Moreover, the distance between the straight line 346 and the straight line 348 is equal to Py. The distance between the straight line 347 and the straight line 349 is also equal to Py.

The assist openings 322 and 325 are arranged at the same pitch (Px) as the main openings 312 in the bit line direction. The assist openings 323 and 324 are also arranged at the same pitch (Px) as the main openings 311. The assist openings 321 and 326 are also arranged at the same pitch (Px) as the main openings 313. That is, the assist openings 321 and 326 deviate by Px/3 along the bit line direction from the assist openings 323 and 324 or the assist openings 322 and 325.

It is appreciated from the above explanation that the assist openings 325, the assist openings 323, the assist openings 321, the main openings 312, the main openings 311, the main openings 313, the assist openings 322, the assist openings 324, and the assist openings 326 are arranged at the same pitch in the oblique direction. That is, the photomask 112 shown in FIG. 3 has a periodicity increased in the oblique direction by the addition of the assist openings 321, 322, 323, 324, 325, and 326.

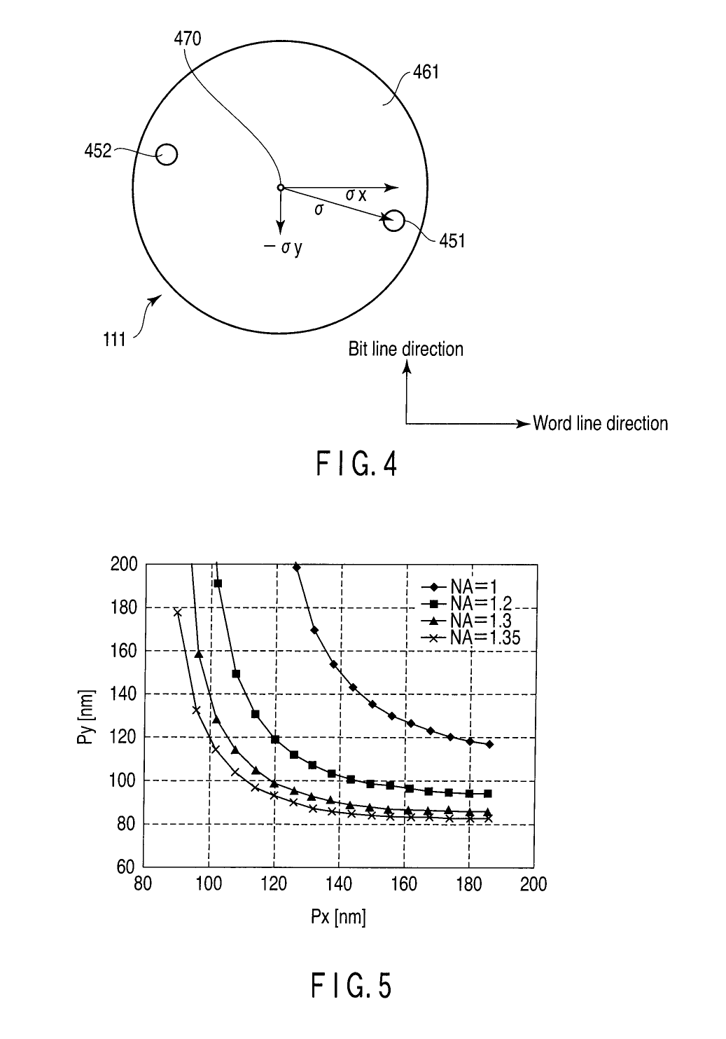

FIG. 4 shows an example of the configuration of the illumination optical system 111 suitable for exposure under conditions where the minimum pattern pitch of the opening patterns is λ/NA in a photolithography technique used for the exposure of the hole patterns. In the present embodiment, modified dipole illumination is used as the illumination optical system 111.

As shown in FIG. 4, the modified dipole illumination 111 has a luminous region (first luminous region) 451 and a luminous region (second luminous region) 452 in a unit circle having a radius of “1”. The luminous regions 451 and 452 are enclosed by a nonluminous region 461.

The luminous region 451 and the luminous region 452 are provided symmetrically with respect to a center 470 of the illumination 111 in the x-direction (±σx) and the y-direction (±σy). That is, the luminous region 451 and the luminous region 452 have the same shape and the same dimensions, and the center of the luminous region 451 and the center of the luminous region 452 are located symmetrically to each other with respect to the center 470 of the illumination 111. Thus, the distance (σ) between the center 470 of the illumination 111 and the center of the luminous region 451 is equal to the distance between the center 470 of the illumination 111 and the center of the luminous region 452. Ideally, the center of the luminous region 451 is coincident with a point (bright spot position) containing the luminous region 451, and the center of the luminous region 452 is coincident with a point containing the luminous region 452.

Bright spot position coordinates σx and σy which determine the distance σ between the center 470 of the illumination 111 and the point containing a luminous region are provided by Expressions (1) and (2):

$$\begin{matrix}{σ}_{x} = \frac{λ}{18 NA} ( \frac{9}{{P}_{x}} + \frac{2 {P}_{x}}{{P}_{y}^{2}} ) & ( 1 ) \\ {σ}_{y} = - \frac{λ}{6 {P}_{y} NA} & ( 2 )\end{matrix}$$

where λ is the wavelength of the illumination light, and NA is the numerical aperture of the projection lens 113 through which the illumination light passes.

On the basis of Expressions (1), (2), the distance σ between the point containing a luminous region and the center 470 of the illumination 111 is provided by Expressions (3) and (4):

$$\begin{matrix}{σ}^{2} = {σ}_{x}^{2} + {σ}_{y}^{2} & ( 3 ) \\ σ = \frac{λ}{18 NA {P}_{x} {P}_{y}^{2}} \sqrt{( 4 {P}_{x}^{2} + 9 {P}_{y}^{2} ) ( {P}_{x}^{2} + 9 {P}_{y}^{2} )} & ( 4 )\end{matrix}$$

Oblique illumination light from the modified dipole illumination 111 is applied to the photoresist on the substrate 114 via the photomask 112, thereby a highly accurate contact hole pattern having controlled dimensional errors can be formed on the photoresist.

That is, in the lithography apparatus used to manufacture the NAND flash memory, σ<1 in general, and therefore Expression (5) is satisfied in accordance with Expression (4):

$$\frac{λ}{18 NA {P}_{x} {P}_{y}^{2}} \sqrt{( 4 {P}_{x}^{2} + 9 {P}_{y}^{2} ) ( {P}_{x}^{2} + 9 {P}_{y}^{2} )} < 1 \qquad ( 5 )$$

Transforming Expression (5) provides Expression (6):

$$\frac{18 {P}_{x} {P}_{y}^{2}}{\sqrt{( 4 {P}_{x}^{2} + 9 {P}_{y}^{2} ) ( {P}_{x}^{2} + 9 {P}_{y}^{2} )}} > \frac{λ}{NA} \qquad ( 6 )$$

The pitch Px of the main patterns 311, 312, and 313 in the photomask 112 in the bit line direction and the pitch Py thereof in the word line direction are determined to satisfy Expression (6). Thus, the bit line contacts CB can be formed with a layout whereby the bit line contacts can be stably formed in the lithography step.

That is, when the bit line contacts CB are arranged in a staggered-for-three form, the pitch Px in the bit line direction and the pitch Py in the word line direction are set to satisfy Expression (6). This can ensure a space between the bit line contacts CB, and therefore simplify the manufacturing process. Therefore, the dimension in the bit line direction can be reduced without increasing the distance between the select gate lines SGD. This can reduce the chip area.

In addition, if Expression (4) is solved with regard to the pitch Py in the word line direction, Expression (7) is obtained:

$${P}_{y} = \sqrt{\frac{λ {P}_{x}^{2} ( 5 λ + \sqrt{64 {NA}^{2} {σ}^{2} {P}_{x}^{2} + 9 {λ}^{2}} )}{72 N {A}^{2} {σ}^{2} {P}_{x}^{2} - 18 {λ}^{2}}} \qquad ( 7 )$$

Next, the relation between the pitch Px of the bit line contacts CB in the bit line direction and the pitch Py thereof in the word line direction is described.

FIG. 5 shows a simulation result based on Expression (7) concerning the relation between the numerical aperture NA of the projection lens 113, and the pitch Px of the bit line contacts CB in the bit line direction and the pitch Py thereof in the word line direction. In this simulation, σ=0.85, and λ=193 nm.

It is apparent from this graph that the optimum value of the pitch Py is lower when the numerical aperture NA is greater for one pitch Px. Moreover, the pitch Py is greater when the pitch Px is smaller for one numerical aperture NA. Therefore, in the staggered-for-three arrangement of the bit line contacts CB, Px=3Py does not necessarily provide a proper layout. The reason is that when the bit line contacts CB are arranged in a staggered-for-three form, the optimum values of the pitches Px and Py change with the numerical aperture NA of the projection lens 113 and the 6 value of the illumination optical system 111. In short, properly setting the pitches Px and Py of the opening patterns 311, 312, and 313 can reduce variations of pattern dimensions in the manufacturing process.

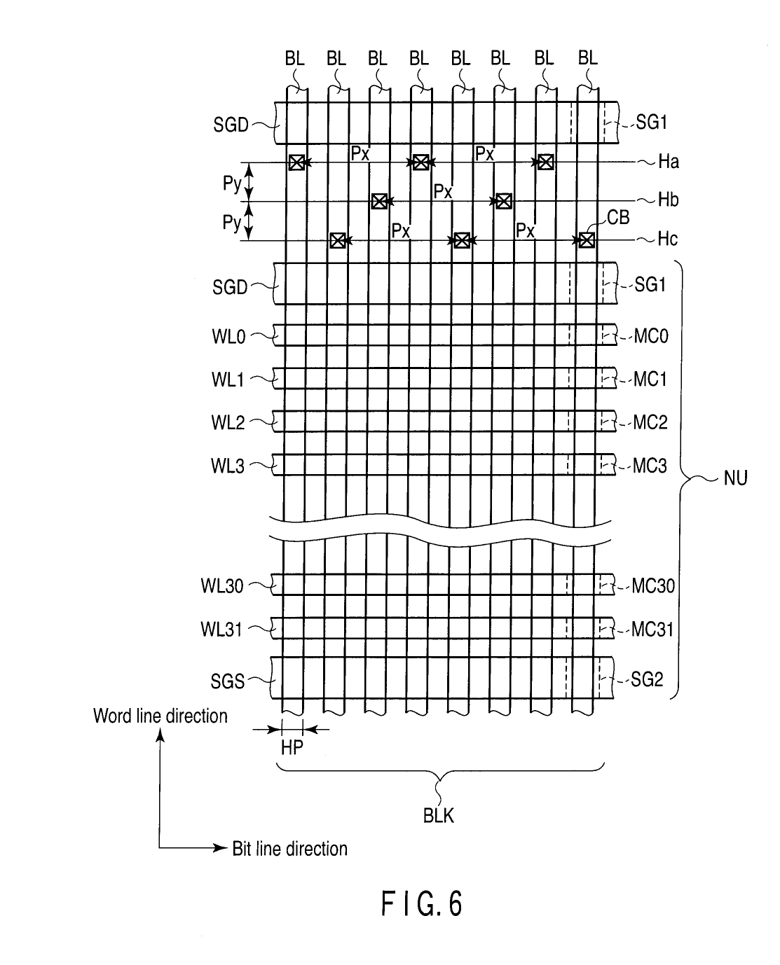

Although three bit line contacts CB for three adjacent bit lines BL are repeatedly arranged on the parallel lines Ha, Hb, and Hc in the mentioned order in the present embodiment (see FIG. 1), the present embodiment is not limited to this. For example, as shown in FIG. 6, the three bit line contacts CB may be arranged on the parallel lines Ha, Hb, and Hc in the mentioned order.

### Second Embodiment

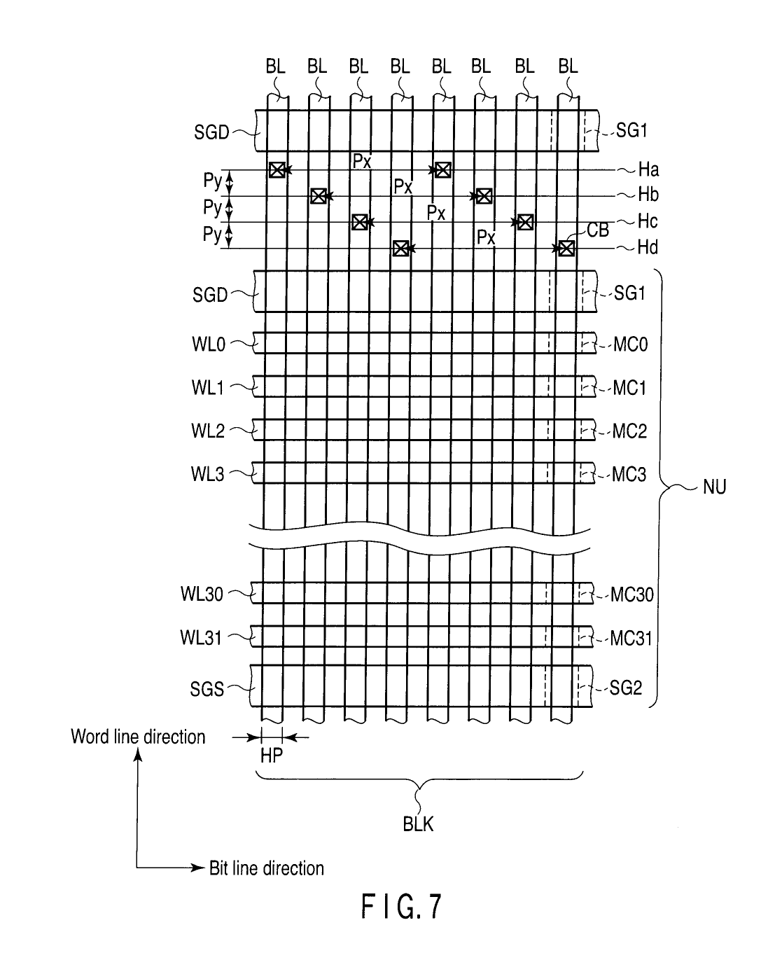

FIG. 7 shows an example of the configuration of a memory cell array in a semiconductor memory device according to the second embodiment of the present invention. In the second embodiment, bit line contacts are arranged in a staggered-for-four form in a NAND flash memory as a nonvolatile semiconductor memory device. The same elements as the elements in the first embodiment are provided with the same reference numerals and are not described in detail.

As shown in FIG. 7, four rows of bit line contacts CB along a bit line direction (second direction) are arranged between select gate lines SGD of adjacent blocks BLK. The bit line contacts CB for adjacent two bit lines deviate from each other in a word line direction (first direction).

For example, bit line contacts CB are arranged at a pitch Px (first interval) on each of four virtual parallel lines Ha, Hb, Hc, Hd extending along the bit line direction. The bit line contacts CB arranged on the first parallel line Ha and the bit line contacts CB arranged on the second parallel line Hb have a pitch Py (second interval) along the word line direction. The bit line contacts CB arranged on the second parallel line Hb and the bit line contacts CB arranged on the third parallel line Hc have a pitch Py along the word line direction. The bit line contacts CB arranged on the third parallel line Hc and the bit line contacts CB arranged on the fourth parallel line Hd have a pitch Py along the word line direction.

In the present embodiment, while the width of the bit line BL is HP, the bit line contacts CB has intervals of 8 HP in each row. That is, when there are four parallel lines, the pitch Px in the bit line direction between the bit line contacts CB formed on each row is four times the pitch of the bit lines BL. Thus, for the bit lines BL 8 HP apart, the bit line contacts CB are arranged at the same position along the word line direction (on the same parallel line). Then, for adjacent bit lines BL, the bit line contacts CB in the respective rows are shifted 2 HP in the word line direction.

In the present embodiment, the minimum distance (Px/4) between the bit line contacts CB adjacent in the bit line direction may be greater than the pitch (2HP) of the bit lines BL. Moreover, when the above-mentioned relation of the pitches Px and Py is satisfied and the centers of the bit line contacts CB are located on the respective parallel lines Ha, Hb, Hc, and Hd, the distance between the parallel lines Ha, Hb, Hc, and Hd is equal to Py.

Thus, even when the bit line contacts CB arranged on the bit lines BL are arranged in a staggered-for-four form, the bit line contacts CB can be highly accurately laid out in a NAND flash memory having thin bit lines BL and having a smaller pitch between the bit lines BL.

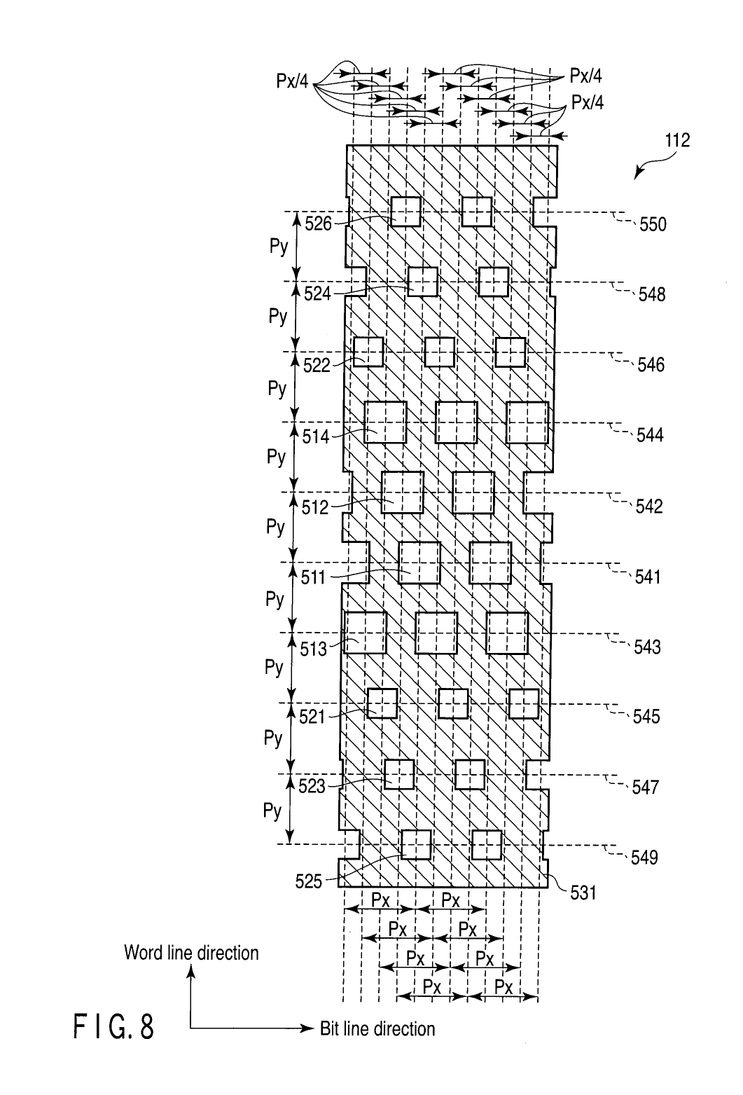

FIG. 8 shows one example of a photomask 112 used to form the bit line contacts CB arranged in a staggered-for-four form. That is, contact holes are dense hole patterns, and are not arranged in the form of an orthogonal grid, and so-called NAND-CB layers are arranged in a staggered-for-four form.

In FIG. 8, the photomask 112 has sets of openings: main openings (first main openings) 511, main openings (second main openings) 512, main openings (third main openings) 513, main openings (fourth main openings) 514, assist openings (first assist openings) 521, assist openings (second assist openings) 522, assist openings (third assist openings) 523, assist openings (fourth assist openings) 524, assist openings (fifth assist openings) 525 and assist openings (sixth assist openings) 526. These openings 511, 512, 513, 514, 521, 522, 523, 524, 525, and 526 are enclosed by a light-blocking region (nontransparent region) 531. The light-blocking region 531 is, for example, a light-blocking region in which a chromium film is formed, or a semitransparent halftone phase shift region in which, for example, a molybdenum silicide film is formed.

The main openings 511, 512, 513, and 514 have the same shape and dimensions. The assist openings 521, 522, 523, 524, 525, and 526 have the same shape and dimensions. The assist openings 521, 522, 523, 524, 525, 526 are smaller than the main openings 511, 512, 513, and 514.

The main openings 511, 512, 513, and 514 are opening patterns (transferred patterns) corresponding to contact hole patterns for the bit line contacts CB. Thus, after a lithography step and a development step, patterns corresponding to the main openings 511, 512, 513, and 514 are formed in a photoresist used for contact hole formation. The assist openings 521, 522, 523, 524, 525, and 526 are auxiliary opening patterns (assist patterns not to be resolved). Therefore, no patterns corresponding to the assist openings 521, 522, 523, 524, 525, and 526 are formed in the photoresist even after the lithography step and the development step.

The main openings 511 are arranged at the pitch Px (second interval) on a straight line (first straight line) 541 extending along the bit line direction. That is, the center of each of the main openings 511 is located on the straight line 541. The main openings 512 adjacent to the main openings 511 are arranged at the pitch Px on a straight line (second straight line) 542 extending along the bit line direction. That is, the center of each of the main openings 512 is located on the straight line 542. The main openings 513 adjacent to the main openings 511 are arranged at the pitch Px on a straight line (third straight line) 543 extending along the bit line direction. That is, the center of each of the main openings 513 is located on the straight line 543. The main openings 514 adjacent to the main openings 512 are arranged at the pitch Px on a straight line (fourth straight line) 544 extending along the bit line direction. That is, the center of each of the main openings 514 is located on the straight line 544.

The straight line 541, the straight line 542, the straight line 543 and the straight line 544 are parallel to each other, and the distance (first distance (second interval) in the first direction) between the straight line 541, the straight line 542, the straight line 543 and the straight line 544 is equal to the pitch Py. Moreover, the main openings 511, the main openings 512, the main openings 513 and the main openings 514 deviate by Px/4 (2HP) from each other along the bit line direction.

The assist openings 521 adjacent to the main openings 513 are arranged at the pitch Px on a straight line (fifth straight line) 545 extending along the bit line direction. That is, the center of each of the assist openings 521 is located on the straight line 545. The assist openings 522 adjacent to the main openings 514 are arranged at the pitch Px on a straight line (sixth straight line) 546 extending along the bit line direction. That is, the center of each of the assist openings 522 is located on the straight line 546. The assist openings 523 adjacent to the assist openings 521 are arranged at the pitch Px on a straight line (seventh straight line) 547 extending along the bit line direction. That is, the center of each of the assist openings 523 is located on the straight line 547. The assist openings 524 adjacent to the assist openings 522 are arranged at the pitch Px on a straight line (eighth straight line) 548 extending along the bit line direction. That is, the center of each of the assist openings 524 is located on the straight line 548. The assist openings 525 adjacent to the assist openings 523 are arranged at the pitch Px on a straight line (ninth straight line) 549 extending along the bit line direction. That is, the center of each of the assist openings 525 is located on the straight line 549. The assist openings 526 adjacent to the assist openings 524 are arranged at the pitch Px on a straight line (tenth straight line) 550 extending along the bit line direction. That is, the center of each of the assist openings 526 is located on the straight line 550.

The straight lines 541, 542, 543, 544, 545, 546, 547, 548, 549 and 550 are parallel to each other. The distance (second interval) between the straight line 543 and the straight line 545 is equal to the pitch Py. The distance between the straight line 544 and the straight line 546 is also equal to the pitch Py. Moreover, the distance between the straight line 545 and the straight line 547 is equal to the pitch Py. The distance between the straight line 546 and the straight line 548 is also equal to the pitch Py. The distance between the straight line 547 and the straight line 549 is equal to the pitch Py. The distance between the straight line 548 and the straight line 550 is also equal to the pitch Py.

In the bit line direction, the assist openings 525, the assist openings 523, the assist openings 521, the main openings 513, the main openings 511, the main openings 512, the main openings 514, the assist openings 522, the assist openings 524 and the assist openings 526 are arranged at the same pitch in the oblique direction. That is, the photomask 112 shown in FIG. 8 has a periodicity increased in the oblique direction by the addition of the assist openings 521, 522, 523, 524, 525, and 526.

When the photomask 112 having such a pattern layout is used in the lithography step for forming the bit line contacts CB in the manufacture of the NAND flash memory, the bit line contacts CB arranged in a staggered-for-four form shown in FIG. 7 can be highly accurately formed.

That is, the pitch Px of the opening patterns 511, 512, 513, and 514 in the photomask 112 in the bit line direction and the pitch Py thereof in the word line direction are determined to satisfy Expression (6). Thus, the bit line contacts CB can be formed with a layout whereby the bit line contacts can be stably formed in the lithography step. This can ensure a space between the bit line contacts CB when the bit line contacts CB are arranged in a staggered-for-four form, and therefore simplify the manufacturing process. Therefore, the dimension in the bit line direction can be reduced without increasing the distance between the select gate lines SGD. This can reduce the chip area.

In the present embodiment as well, Px=4Py does not necessarily provide a proper layout in the staggered-for-four arrangement of the bit line contacts CB. The reason is that when the bit line contacts CB are arranged in a staggered-for-four form, the optimum values of the pitches Px and Py change with the numerical aperture NA of the projection lens 113 and the σ value of the illumination optical system 111. In short, properly setting the pitches Px and Py of the opening patterns 511, 512, 513, and 514 can reduce variations of pattern dimensions in the manufacturing process.

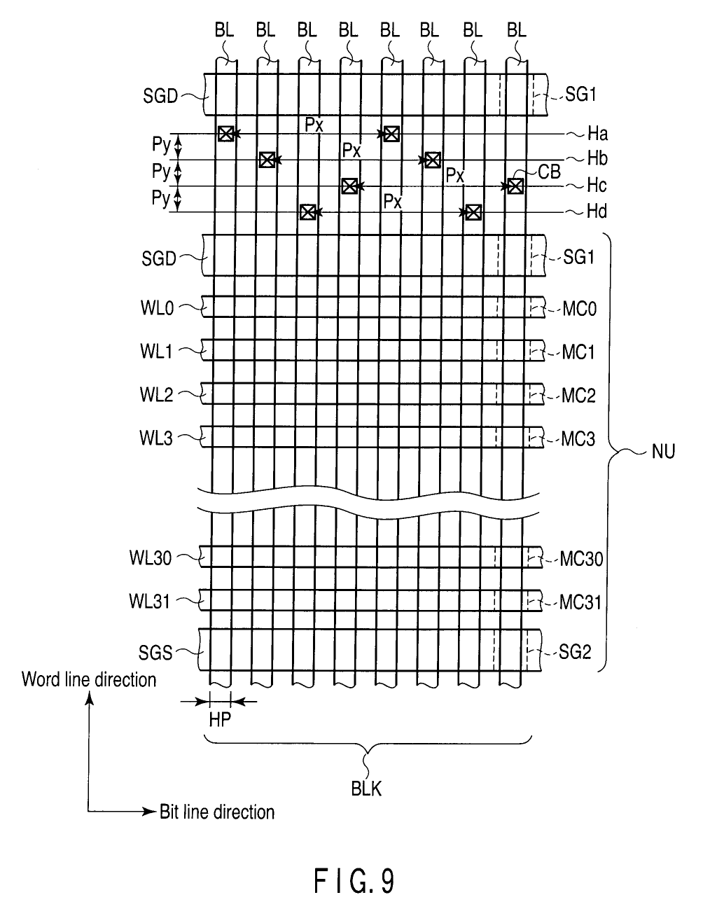

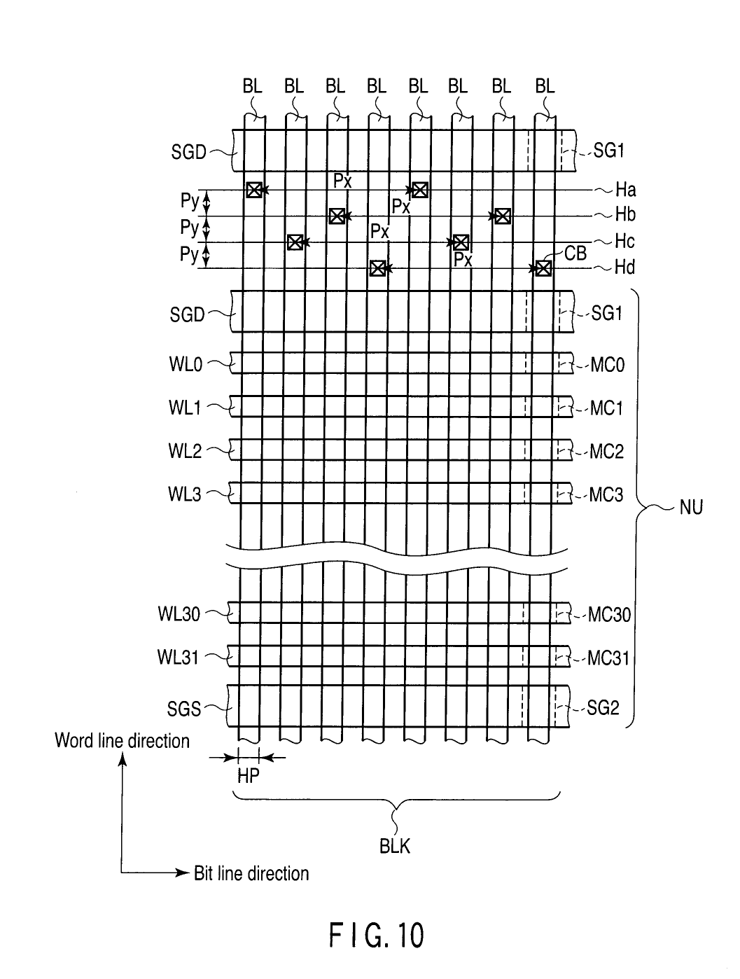

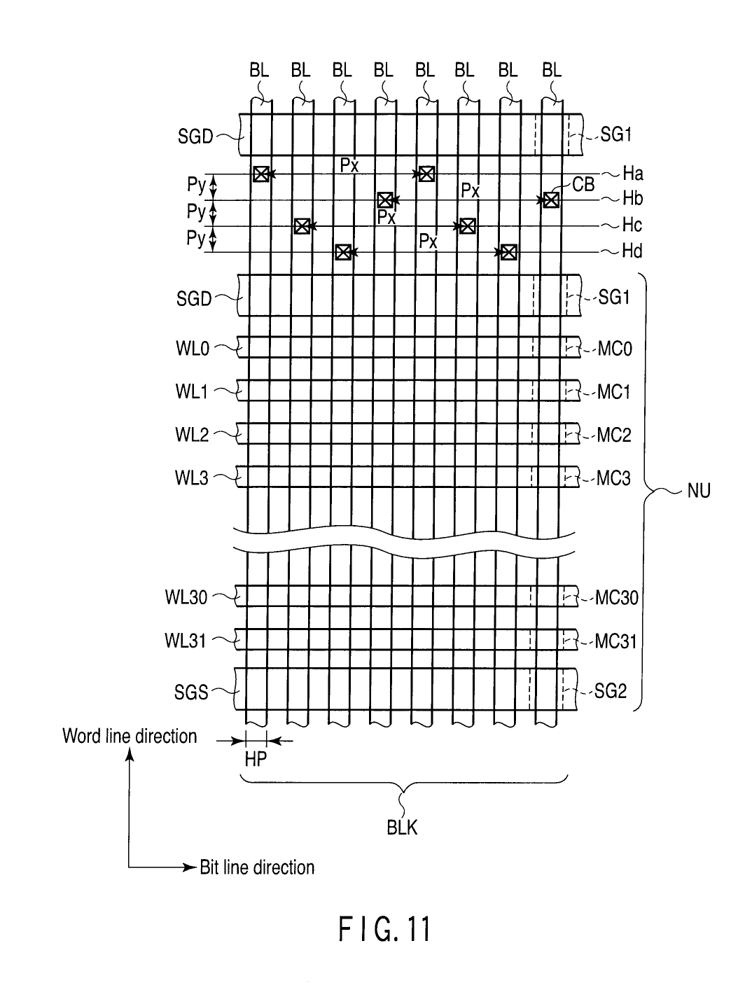

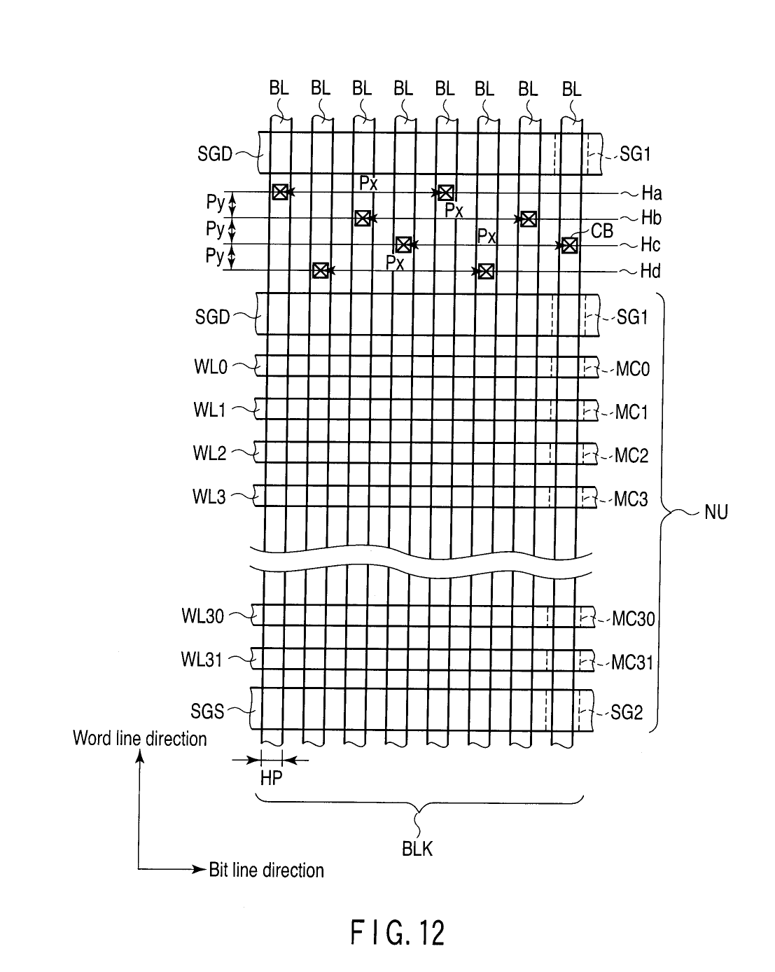

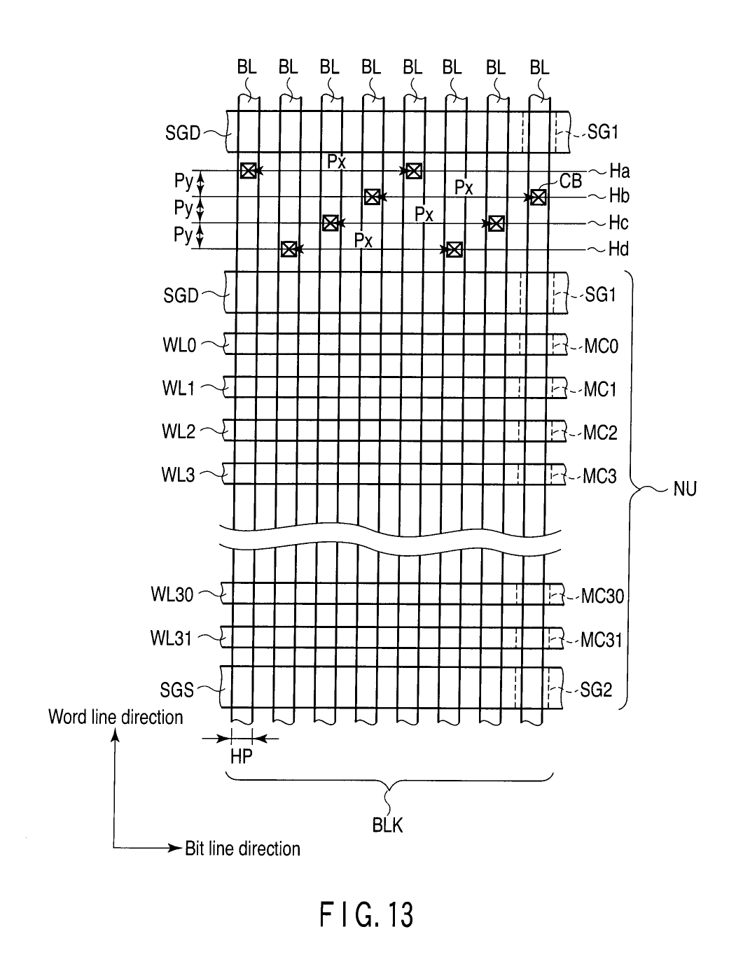

Although four bit line contacts CB for four adjacent bit lines BL are repeatedly arranged on the parallel lines Ha, Hb, Hc, and Hd in the mentioned order in the present embodiment (see FIG. 7), the present embodiment is not limited to this. For example, as shown in FIG. 9, the four bit line contacts CB may be arranged on the parallel lines Ha, Hb, Hd, and Hc in the mentioned order. Alternatively, for example, as shown in FIG. 10, the four bit line contacts CB may be arranged on the parallel lines Ha, Hc, Hb, and Hd in the mentioned order. Alternatively, for example, as shown in FIG. 11, the four bit line contacts CB may be arranged on the parallel lines Ha, Hc, Hd, and Hb in the mentioned order. Alternatively, for example, as shown in FIG. 12, the four bit line contacts CB may be arranged on the parallel lines Ha, Hd, Hd, Hb, and Hc in the mentioned order. Alternatively, for example, as shown in FIG. 13, the four bit line contacts CB may be arranged on the parallel lines Ha, Hd, Hc, Hb in the mentioned order.

As described above, in the NAND flash memory which requires the interconnect patterning of “HP×NA/λ<0.15”, the bit line contacts CB are arranged on each of three or more parallel lines extending along the bit line direction so that the bit line contacts CB are apart from each other by a multiple of a natural number equal to or more than three which is the period of the bit lines BL. That is, three or more rows of bit line contacts provided between the select gate lines of adjacent two blocks are arranged in a staggered form. This can not only simplify the manufacturing process but also ensure a space between the bit line contacts. Therefore, even when the dimension in the bit line direction is reduced, the bit line contacts can be arranged without increasing the distance between the select gate lines in the word line direction. This can reduce the chip area.

It is also possible to improve a margin for short-circuit caused by the decrease of the period of the bit lines, a margin for a breakdown voltage across the memory cells adjacent in the word line direction, and the quality of the formation of the bit line contacts in the lithography step.

Although the period of the arrangement of the bit line contacts CB starts with the parallel line Ha in the embodiments described, the present invention is not limited to this.

Furthermore, the bit line contacts CB are not exclusively arranged in a staggered-for-three form or a staggered-for-four form, and can also be arranged in a staggered-for-five form or in a more staggered form.

Still further, six rows of assist openings are provided on the photomask in the embodiments described, but the embodiments are not limited to this. For example, eight or more rows of assist openings or eight or less rows of assist openings may be provided.

Further yet, the main openings and the assist openings are not necessarily square, and may be, for example, rectangular, circular or elliptic.

Further yet, the pitch Py of the bit line contacts (main openings) in the word line direction does not necessarily have to be constant.

Further yet, the illumination optical system is not limited to the modified dipole illumination, and, for example, modified illumination such as modified quadrupole illumination or modified hexapole illumination can be used.

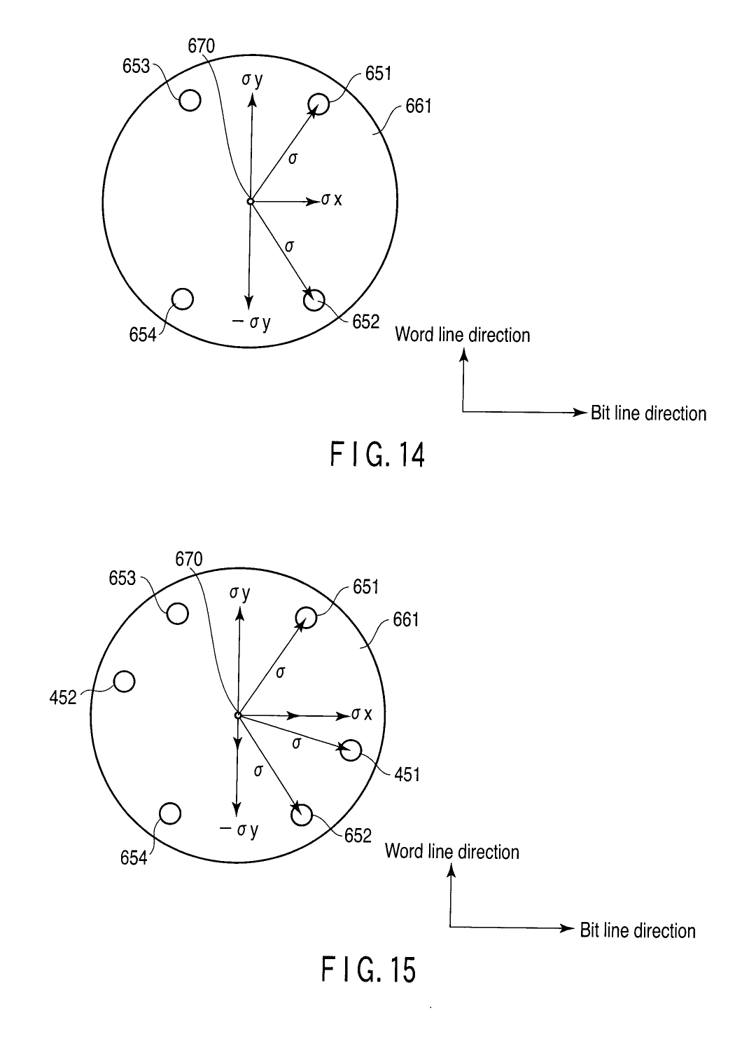

For example, as shown in FIG. 14, the modified quadrupole illumination has a luminous region (first luminous region) 651, a luminous region (second luminous region) 652, a luminous region (third luminous region) 653 and a luminous region (fourth luminous region) 654. The luminous regions 651, 652, 653, and 654 are enclosed by a nonluminous region 661.

For example, as shown in FIG. 15, the modified hexapole illumination has luminous regions (fifth and sixth luminous regions) 451 and 452 and luminous regions (first to fourth luminous regions) 651, 652, 653, and 654. The luminous regions 451, 452, 651, 652, 653, and 654 are enclosed by a nonluminous region 661.

In addition, the luminous regions of the modified illumination are not necessarily circular in each case, and may be, for example, elliptic or fan-shaped.

Moreover, while the bit line contacts in the NAND flash memory are described by way of example in the embodiments, the embodiments are not limited to this. For example, the embodiments can also be applied to interconnect contacts in various semiconductor memory devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate on which memory cells are formed;
interconnects arranged along a first direction above the semiconductor substrate and having regular intervals along a second direction perpendicular to the first direction; and
interconnect contacts which connect the interconnects and the semiconductor substrate and are arranged on three or more rows, a center of each of two of the interconnect contacts connected to the interconnects adjacent in the second direction deviating from each other along the first direction.

2. The device according to claim 1, wherein
the minimum distance between two of the interconnect contacts adjacent along the second direction on each of the rows is greater than the a pitch of the interconnects.

3. The device according to claim 1, wherein
a pitch of the interconnect contacts along the second direction on each of the rows is a multiple of a natural number equal to or more than three of a pitch of the interconnects.

4. The device according to claim 1, wherein
the number of the rows is three, and
three interconnect contacts provided on the respective rows are repeatedly arranged in the same order along the second direction.

5. The device according to claim 4, wherein
a pitch of the interconnect contacts arranged on each of the rows along the second direction is three times a pitch of the interconnects.

6. The device according to claim 4, wherein
a center of each of three interconnect contacts arranged on the respective rows deviates from each other at a regular pitch along the first direction.

7. The device according to claim 1, wherein
the number of the rows is four, and
four interconnect contacts provided on the respective rows are repeatedly arranged in the same order along the second direction.

8. The device according to claim 7, wherein
a pitch of the interconnect contacts arranged on each of the rows along the second direction is four times a pitch of the interconnects.

9. The device according to claim 7, wherein
a center of each of four interconnect contacts arranged on the respective rows deviates from each other at a regular pitch along the first direction.

10. A semiconductor memory device comprising:
a semiconductor substrate on which memory cells are formed;
bit lines arranged along a first direction above the semiconductor substrate and having regular intervals along a second direction perpendicular to the first direction; and
bit line contacts which connect the bit lines and the semiconductor substrate, a predetermined number of the memory cells connected in series constituting a first set and a second set adjacent to the first set, the bit line contacts being provided between select gate lines between the first and second sets, the bit line contacts being arranged on three or more rows, a center of each of two of the bit line contacts connected to the bit lines adjacent in the second direction deviating from each other along the first direction.

11. The device according to claim 10, wherein
the minimum distance between two of the bit line contacts adjacent along the second direction on each of the rows is greater than the a pitch of the bit lines.

12. The device according to claim 10, wherein
a pitch of the bit line contacts along the second direction on each of the rows is a multiple of a natural number equal to or more than three of a pitch of the bit lines.

13. The device according to claim 10, wherein
the number of the rows is three, and
three bit line contacts provided on the respective rows are repeatedly arranged in the same order along the second direction.

14. The device according to claim 13, wherein
a pitch of the bit line contacts arranged on each of the rows along the second direction is three times a pitch of the bit lines.

15. The device according to claim 13, wherein
a center of each of three bit line contacts arranged on the respective rows deviates from each other at a regular pitch along the first direction.

16. The device according to claim 13, wherein
in each set of three bit line contacts for three adjacent bit lines, an order in which the three bit line contacts are provided along the second direction does not correspond to an order of arrangement of the three bit lines.

17. The device according to claim 10, wherein
the number of the rows is four, and
four bit line contacts provided on the respective rows are repeatedly arranged in the same order along the second direction.

18. The device according to claim 17, wherein
a pitch of the bit line contacts arranged on each of the rows along the second direction is four times a pitch of the bit lines.

19. The device according to claim 17, wherein
a center of each of four bit line contacts arranged on the respective rows deviates from each other at a regular pitch along the first direction.

20. The device according to claim 17, wherein
in each set of four bit line contacts for four adjacent bit lines, an order in which the four bit line contacts are provided along the second direction does not correspond to an order of arrangement of the four bit lines.
